(19) United States
(12) Patent Application Publication
(10) Pub. No.: US 2025/0105924 A1
(43) Pub. Date: Mar. 27, 2025

(54) METHOD FOR DETERMINING PHASE INFORMATION RELATED TO AN RF TRANSMISSION CHANNEL AND RADAR MMIC DEVICE

(71) Applicant: Infineon Technologies AG, Neubiberg (DE)

(72) Inventors: Michael GERSTMAIR, Langenstein (AT); Alexander Michael MELZER, Alberndorf in der Riedmark (AT); Josef KULMER, Graz (AT); Gunther KRAUT, Egmating (DE); Tobias BUCKEL, Großohrenbronn (DE)

(21) Appl. No.: 18/888,949

(22) Filed: Sep. 18, 2024

(30) Foreign Application Priority Data
Sep. 27, 2023 (DE) 102023209463.0

(51) Int. Cl. H04B 17/12; G01R 23/16; H04B 17/15; H04B 17/21

(52) U.S. Cl. CPC H04B 17/12; G01R 23/16; H04B 17/15; H04B 17/221

(57) ABSTRACT

A method for determining phase information related to an RF transmission channel includes generating a frequency-modulated RF signal including a frequency ramp, coupling a first representation of the frequency-modulated RF signal to the RF transmission channel to generate a first frequency-modulated RF output signal, and coupling a second representation of the frequency-modulated RF signal to a test phase shifter. Measurement samples are generated during the frequency ramp based on phase shifting the second representation of the frequency-modulated RF signal according to a set of phase shift values to generate a frequency-modulated RF test signal, generating a down-converted signal based on mixing a first representation of the first frequency-modulated RF output signal with the frequency-modulated RF test signal, sampling the down-converted signal to generate, for each phase shift value, a respective measurement sample, and computing the phase information related to the RF transmission channel based on the measurement samples.

### CROSS-REFERENCE TO RELATED APPLICATION

This application claims priority to Germany Patent Application No. 102023209463.0 filed on Sep. 27, 2023, the content of which is incorporated by reference herein in its entirety.

### TECHNICAL FIELD

The present disclosure relates to the field of determining phase information related to an RF transmission channel and in particular of determining phase information of a transmission channel of a radar monolithic microwave integrated circuit (MMIC) device.

### BACKGROUND

Radar sensors using at least one radar monolithic microwave integrated circuit (MMIC) device are used today in many cars and other vehicles for assisting the driver or providing autonomous driving. Such applications require a high degree of safety as a failure of the radar MMIC device or an operation outside the specified operating range of the radar MMIC device may lead to an unreliable operation or a failure of the assisting system. Typically, several safety goals of a radar MMIC device are defined towards certain transmit signal parameters. These parameters are typically monitored by the radar MMIC device in order to achieve the required level of safety.

Typically, phase and amplitude balance between all transmission (TX) channels involved in a radar measurement need to be within a certain range in order to guaranty an operation as defined in the device specification. For the phases of the transmission channels, typically only a few degrees of phase imbalances are allowed.

In view of the above, a need exists for a concept to provide an improved determining of phase information for a transmission channel of a radar MMIC.

### SUMMARY

According to one example, a method for determining phase information related to an RF transmission channel includes generating a frequency-modulated RF signal, the frequency-modulated RF signal including a frequency ramp, coupling a first representation of the frequency-modulated RF signal to the RF transmission channel to generate a first frequency-modulated RF output signal, and coupling a second representation of the frequency-modulated RF signal to a test phase shifter. A set of measurement samples is generated during the frequency ramp, the set of measurement samples being generated based on setting, during the frequency ramp, a phase shift provided by the test phase shifter to each phase shift value of a predetermined set of phase shift values and phase shifting the second representation of the frequency-modulated RF signal according to the respective phase shift value to generate a frequency-modulated RF test signal, generating a down-converted signal based on mixing a first representation of the first frequency-modulated RF output signal with the frequency-modulated RF test signal, sampling the down-converted signal to generate for each phase shift value of the set of phase shift values a respective measurement sample of a set of measurement samples, and computing the phase information related to the RF transmission channel based on the set of measurement samples.

According to a further example, a radar MMIC device includes a local oscillator to generate a frequency-modulated RF signal including a frequency ramp, an RF transmission channel, a test phase shifter, and a first coupler configured to couple a first representation of the frequency-modulated RF signal to the RF transmission channel and a second representation of the frequency-modulated RF signal to the test phase shifter. The RF transmission channel is configured to generate a first frequency-modulated RF output signal based on the frequency-modulated RF signal, and the test phase shifter is configured to phase-shift the second representation of the frequency-modulated RF signal according to a phase shift applied to the test phase shifter and to generate a frequency-modulated RF test signal. A second coupler is coupled to the RF transmission channel to generate a first representation of the frequency-modulated RF output signal. A mixer is coupled to the test phase shifter and the second coupler to receive the first representation of the frequency-modulated RF output signal and the frequency-modulated RF test signal, wherein the mixer is further configured to generate a down-converted signal based on mixing the first representation of the frequency-modulated RF output signal with the frequency-modulated RF test signal. A controller is configured to set the phase shift applied to the test phase shifter during the frequency ramp to each phase shift value of a predetermined set of phase shift values. A sampler is provided to sample the down-converted signal to generate for each phase shift value of the set of phase shift values a respective measurement sample of a set of measurement samples. A processor computes phase information related to the transmission channel based on the set of measurement samples.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a circuit diagram according to an example.

FIGS. 2A to 2C illustrate a generating of a set of measurement samples according to an example.

FIG. 3 illustrates estimation of a phase error according to an example.

FIG. 4 illustrates a further example of generating a set of measurement samples.

FIG. 5 illustrates a flow diagram according to an example.

### DETAILED DESCRIPTION

The examples described herein provide a new concept for determining phase information for calibration and monitoring routines. The new concept allows to reduce the spectral power density generated during the determining of the phase information and further allows in some examples to determine the phase information during the in-the field operation of the radar MMIC device based on frequency-modulated continuous wave (FMCW) signals.

Existing solutions use continuous wave signals from the phased locked loop (PLL) having a constant frequency for determining phase information of a transmission channel. Distinguished therefrom, using a FMCW signal for the determining of phase information achieves a significant reduction of the mean power spectral density emitted by the MMIC device during operation as the frequency of the signal used for determining the phase information is no longer concentrated at one frequency but spread over a band of frequencies. This allows to stay within emission requirements of standard bodies such as ETSI (European Telecommunications Standards Institute) without the need of a reduction of the transmission power.

In addition, the same type of signals, e.g., FMCW signals, are used for the specified in-field operation (e.g., determining range, velocity or direction-of-arrival) and the monitoring or calibration. Accordingly monitoring and calibration is done under realistic conditions and the safety level is increased. Furthermore, the measurement is done during only one frequency ramp which allows a fast determining of the phase information suitable for in the field operation.

The determining of the phase information can be done periodically during the in-field operation for example between respective FMCW ramps (chirps) or between a frame of FMCW ramps.

In other examples, the same FMCW signal transmitted during a frequency ramp for detecting range, velocity or angle of arrival of objects can be used for monitoring and calibration.

The determining of the phase information as proposed herein allows the required components to be integrated in one semiconductor chip (e.g., one MMIC chip) and the concept therefore may be implemented as a chip internal measurement (all required steps are performed in one semiconductor chip).

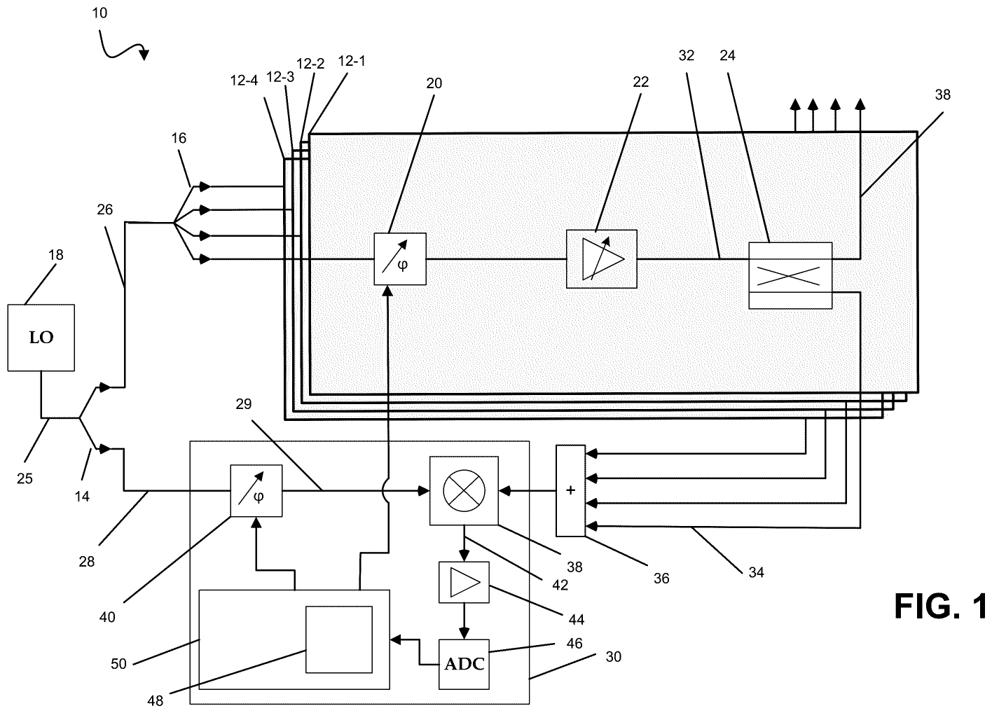

Referring now to FIG. 1, a radar device 10 is shown to include a plurality of transmission channels 12-1, to 12-4 for generating transmission signals. The radar device 10 may be a MMIC semiconductor chip and further functionalities such as receiving channels which may be implemented in the radar device 10 are omitted in FIG. 1 for the sake of clarity. Each input of a respective transmission channel is coupled via a first coupler 14 and a second coupler 16 to a local oscillator (LO) 18. The first coupler 14 and the second coupler 16 are implemented as splitters which may be formed by passive components. Each transmission channel includes a phase shifter 20 (herein after referred to as transmit phase shifter 20), a power amplifier 22 and a coupler 24. Each of the transmission channels 12-1, to 12-4 may include other components which are not shown for simplicity. The local oscillator 18 is configured to generate a frequency-modulated radio frequency (RF) signal 25 (frequency-modulated RF signal 25) including a frequency ramp. In examples, the frequency-modulated RF signal 25 is a frequency-modulated continuous wave signal (FMCW signal) which includes a linear frequency ramp having a start frequency and a stop frequency. The frequency ramp may be a rising ramp such that the frequency increases with time or a falling ramp such that the frequency decreases with time.

The frequency-modulated RF signal 25 is split by the first coupler 14 in a first representation of the frequency-modulated RF signal (herein referred to as transmission path signal 26) and a second representation of the frequency-modulated RF signal (herein referred to as test path signal 28). The transmission path signal 26 and the test path signal 28 are replicas of the frequency-modulated RF signal with a reduced power level compared to the LO signal. The test path signal 28 is transferred to test circuitry 30 which will be described below in more detail. The transmission path signal 26 is coupled to an input of the second coupler 16. The second splitter 16 splits the transmission path signal 26 into 4 representations which are transferred via outputs of the second splitter 16 to the transmission channels 12-1 to 12-4, respectively. The transmission channel 12-1 to 12-4 can be controlled to be activated for processing or deactivated, for example by enabling the power amplifier 22 or disabling the power amplifier 22. During radar processing operation all or a set of the transmission channels transmission channels 12-1, to 12-4 may be activated, for example. During the monitoring or calibration operation which will be described below, only one of the plurality of transmit channels may be activated.

The activated transmission channel processes the received transmission path signal 26 by applying a respective phase shift via the transmit phase shifter 20 and amplifying the phase shifted transmission path signal 26 to generate a frequency-modulated RF output signal 32. The frequency-modulated RF output signal 32 is transferred to an input of the coupler 24 which couples a first representation 34 of the frequency-modulated RF output signal 32 to an input of a combiner 36. A second representation 38 of the frequency-modulated RF output signal 32 may be transmitted to an antenna port associated with the respective transmission channel. The second representation may be a main portion of the frequency-modulated RF output signal 32, e.g., the signal power of the second representation 38 may be higher than the signal power of the first representation 34.

The combiner 36 may include an input associated with each of the transmission channels 12-1, to 12-4 which is coupled to the coupler 24 of the respective transmission channel. The combiner 36 couples the first representation 34 of the frequency-modulated RF output signal 32 to a first input of a mixer 38 (herein also referred as test mixer 38) of the test circuitry 30.

The test circuitry 30 further includes a phase shifter 40 (herein also referred to as a test phase shifter 40). In some examples, the test phase shifter 40 may include a passive phase shifter which increases the accuracy of the phase shifting. An input of the test phase shifter 40 is coupled to an output of the coupler 14 to receive the test path signal 28. The test phase shifter 40 applies a phase shift to the test path signal 28 to generate a frequency-modulated RF test signal 29 having a phase shift according to a phase shift value applied to the test phase shifter 40 by a controller 50. An output of the test phase shifter 40 is coupled to a second input of the test mixer 38 to transfer the frequency-modulated RF test signal 29 to the test mixer 38. The test mixer 38 mixes the two signals (herein also referred to as down-converting) and provides at an output a down-converted signal 42 which may be amplified by an optional amplifier 44. The amplified down-converted signal 42 is provided to an analog-to-digital converter 46 to generate a set of measurement samples as will be described in more detail below.

The set of measurement samples is provided to a processor 48 configured to compute phase information related to the respective transmission channel. The controller 50 is configured to set a phase shift applied to the test phase shifter 40 during the frequency ramp to each phase shift value of a predetermined set of phase shift values as will be described in more detail. The controller 50 further controls the sampling of the measurement samples such that for each phase shift value of the set of phase shift values at least one measurement sample is generated. The controller 50 and the processor 48 may be implemented as hardware circuit, software, firmware or any combination thereof. The processor 48 may for example include a Goertzel filter or an FFT circuit and a programmable arithmetic logic unit or a digital processor capable of performing processing data or executing programming steps. In some examples, the controller 50 may fully or partially utilize the same components or may be implemented as one unit. For example, the controller 50 may use the processor 48 for performing control operations.

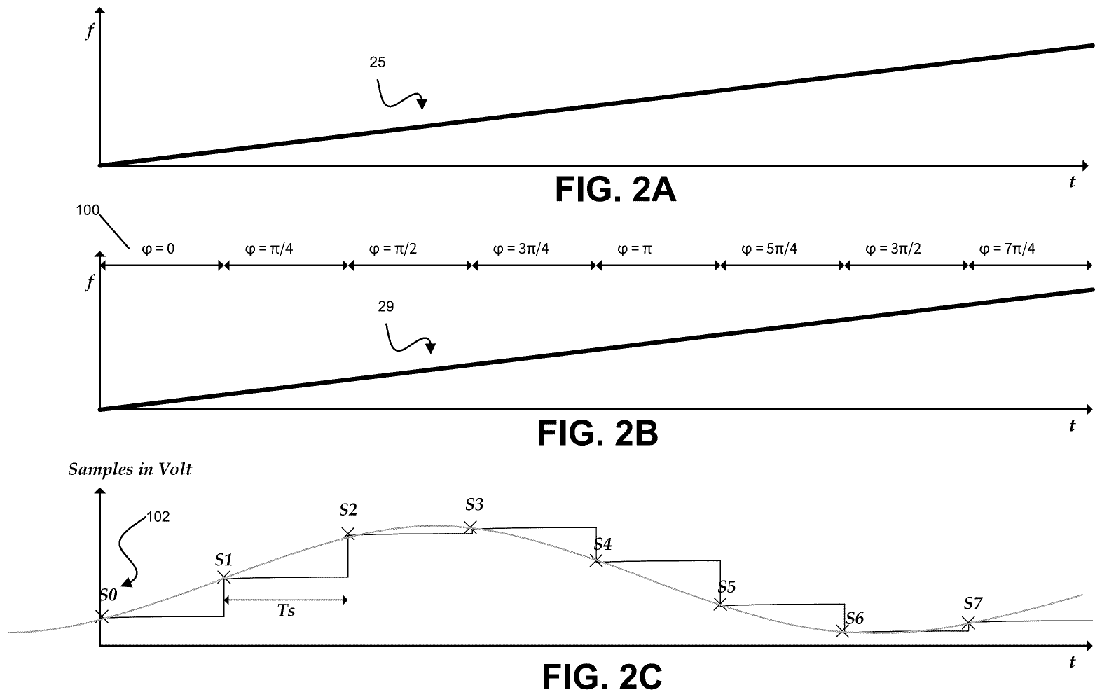

Referring now to FIGS. 2A to 2C, the setting of the phase shift and the sampling of the measurement samples during the frequency ramp will be described in more detail. FIG. 2A shows the frequency of the frequency-modulated RF signal 25 as a function of time during a frequency ramp. FIG. 2A shows the frequency of the frequency-modulated RF signal 25 to increase linearly during the frequency ramp from a start frequency to a stop frequency. In other examples the frequency may decrease linearly. While the examples shown herein use a linear frequency ramp, other examples may deviate from a linear ramp characteristic. The start frequency and the stop frequency may for example be within a dedicated radar band for example between 76 GHz and 81 GHz.

FIG. 2B shows the phase shift applied by the test phase shifter 40 to generate the frequency-modulated RF test signal 29. During the frequency ramp of the frequency-modulated RF test signal 28 (which corresponds to the frequency ramp of the frequency-modulated RF signal 25), each phase shift value of a set 100 of phase shift values is applied to the test phase shifter 40 for providing the corresponding phase shift to the frequency-modulated RF test signal 29. In other words, the frequency-modulated RF test signal 29 can be considered as partitioned into a sequence of time intervals. During a respective time interval of the sequence of time intervals, the frequency-modulated RF test signal 29 contains a phase shift in accordance with a phase shift value of the set 100 of phase shift values assigned to this time interval. In the example of FIG. 2B, the phase shift value is a sequence of eight phase shift values which increase in equidistant steps from 0 to 7π/4. While FIG. 2B shows eight phase shift values applied during the frequency ramp, it is to be noted that in other examples other numbers of phase shift values may be applied. The number of phase shift values may be N and the phase shift values may increase from 0 to 2π(N−1)/N. Furthermore, it is to be noted that the set 100 of phase shift values may contain in other examples a sequence of decreasing phase shift values. FIG. 2B shows the time intervals during which the respective phase shifts are applied to have a same time duration. However in other examples the time duration may not be equal.

As described previously, the frequency-modulated RF test signal 29 is mixed with the first representation 34 of the frequency-modulated RF output signal 32 to generate the down-converted signal 42.

The frequency-modulated RF test signal 29 can be described by

$${s}_{PMLO} ( t ) = {A}_{1} \cdot cos ( 2 π {f}_{0} t + π k {t}^{2} + {φ}_{IQM} ) ,$$

where S_{PMLO} is the frequency-modulated RF test signal 29, t is the time in the interval [0, T] with T being the time duration of the frequency ramp, k is the slope of the frequency ramp, f₀ being the start frequency of the frequency ramp and A1 is a constant amplitude. φ_{IQM} is the phase shift in radians applied by the test phase shifter 40 and can be denned by

$${φ}_{IQM} = 2 π \frac{n}{N}$$

where N is the number of phase shift values in the set of phase shift values and n=0,1, . . . , N−1 being an index defined by a sequence of integer numbers.

The first representation 36 of the frequency-modulated RF output signal 34 can be described by

$${s}_{T X} ( t ) = {A}_{2} \cdot cos ( 2 π {f}_{0} ( t - τ ) + π {k ( t - τ )}^{2} + {φ}_{T X} )$$

where S_{TX}(t) is the first representation 36 of the frequency-modulated RF output signal 34, φ_{TX} is the configured phase shift applied by the phase shifter 20 in the respective transmission channel and t represents the difference in arrival time (herein also referred to as RF delay time) between the signals S_{PMLO}(t) and S_{TX}(t) at the test mixer 40. As depicted in FIG. 1, τ results from the signal delay caused by additional circuit components of the transmission channel.

After the mixing, the down-converted signal 42 is obtained as

$$mixout ( t ) = A1A2 \frac{cos \{ 2 π k {t}^{2} - 2 π k τ t + 4 π {f}_{0} t + {φ}_{T X} + π k {τ}^{2} - 2 π {f}_{0} τ + \frac{2 π n}{N} \}}{2} + A 1 A 2 \frac{cos \{ 2 π k τ t - {φ}_{T X} - π k {τ}^{2} + 2 π {f}_{0} τ + \frac{2 π n}{N} \}}{2}$$

where mixout(t) is the down-converted signal 42.

Taking into account that in the first summand of mixout(t) the term 4πf₀t corresponds to a frequency of 2f₀ which is in the range of ten(s) or hundred(s) of GHz and the other time-dependent terms 2πkτt and 2πkt² only slightly modify this frequency, the first summand can be neglected due to the lowpass-filtering characteristic of the circuits after the test mixer 38 (e.g., amplifier 44) and the down-converted signal 42 at the input of the analog-to-digital converter 46 can be represented by

$$s ( t ) = \frac{{A}_{1} \cdot {A}_{2}}{2} \cdot cos ( 2 π k τ t + 2 π {f}_{{0}^{τ}} - π k {τ}^{2} + \frac{2 π n}{N} - {φ}_{T X} ) .$$

Note that the difference in arrival time τ introduces an oscillation in the down-converted signal 42 with the frequency kτ. It is further to be noted that for τ=0 (no difference in arrival time) the down-converted signal 42 would be a DC value which matches the DC value obtained when using a continuous wave signal without frequency modulation (k=0). The phase term of this function is determined by φ=2πf₀τ−πkτ²−φ_{TX}. Assuming a sampling of the down-converted signal 42 time-aligned with the setting of the phase shifts every nTs where Ts is the sampling interval and n is the index variable introduced previously, the sampled down-converted signal s[n] can be regarded as a set of measurement values of

$$s [ n ] = s ( n {T}_{s} ) = \frac{{A}_{1} \cdot {A}_{2}}{2} \cdot cos ( 2 π n ( k τ {T}_{s} + \frac{1}{N} ) + 2 π {f}_{0} τ - {φ}_{T X} ) .$$

Note that the term πkτ² has been approximated to be zero as t is in the picosecond range. Time aligning may in examples include that a time interval between two consecutive settings of the phase shift corresponds to a time interval between two consecutive samplings of measurement samples which allows reducing efforts in the processing and implementation.

FIG. 2C shows an example of a set of measurement samples 102 which are taken with a sampling time Tₛ. Accordingly, the set of measurement values s[n] contains N discrete measurement points constituting one sampled period of a cosine wave as a function of the index variable n. FIG. 2C shows the sampled value in Volt of eight measurement samples s1 . . . s7 versus time and for illustration purpose the corresponding cosine function s (t) as outlined above is illustrated.

The frequency of the first-order harmonic function is defined by 2πn(kτTₛ+1/N). Compared to a continuous wave signal, the usage of a frequency-modulated signal introduces an additional frequency component 2πkτTₛ which can be regarded as an error frequency. The phase term of this first order harmonic function is obtained as 2πf₀τ−φ_{TX}.

It is to be noted that all information to determine amplitude and phase parameters can be derived by a Fast-Fourier Transformation (FFT) or a single point Digital Fourier Transformation (using for example a Goertzel-filter) from the first-order harmonic bin value (bin with frequency index 1 from a set of frequency indices m=0, 1, . . . . M−1, with M=N) of the Fourier-Transformation result (first-order harmonic Fourier coefficient). The result can be used to calibrate and/or monitor safety relevant transmission parameters within the radar device 10.

The first order harmonic bin value is a complex-value and can be written as z1=Re(z1)+Im(z1), where Re is the real part of the complex-valued first order harmonic bin and Im is the imaginary part of the complex-valued first order harmonic bin value.

Under the assumption that πkτ² is small, the phase term 2πf₀τ−φ_{TX} can be derived for example by determining or estimating the inverse tangent of (Im(z1)/Re(z1)) or arctan 2 (Im (z1),Re Im(z1)). The inverse tangent or arctan 2 can for example be estimated using a Cordic-implementation or using a processor capable of calculating or estimating the inverse tangent function.

It is to be noted that the phase term 2πf₀τ−φ_{TX} contains the phase φ_{TX} of the transmission channel to be determined and a factor 2πf₀τ caused by the difference in arrival times t which is the same for all transmission channels. From determining the above phase term between two or more transmission channels, the relative phase information between the channels can be determined which allows calibration and monitoring of the transmitting channels relative to each other.

Furthermore, it is to be noted that due to the discrete sampling, a phase error may be introduced considering that a frequency-modulated RF signal and not a signal of fixed frequency is used as test signal. The phase error can be estimated by the integral of the error frequency introduced above over the full harmonic swing. Since s[n] represents a digital signal, the integral can be replaced by a sum and the analytical phase error can be estimated by

$$e = \frac{1}{N} \cdot {\sum }_{n = 0}^{N - 1} 2 π k τ n {T}_{s} = π k τ {T}_{s} ( N - 1 ) .$$

The introduced error and therefore a post-processing error correction depends on the slope k of the ramp, the sampling interval Ts and the number N of phase shifts in the sequence of phase shifts. All theses parameters can be determined or are known and the phase error can be calculated and corrected based on these parameters. The RF delay time t can be estimated from the zero-order harmonic bin (DC mean value). Considering the following values k=1 MHz/μs, Ts=3 μs, N=8 and τ=250 ps which are typical values for a radar application, the expected error calculates to e=0.945°.

The test circuitry 30 of the radar device 10 estimates the deviation from the true phase value φ_{TX} based on applying a Fourier transform on s [n]. This in further consequence leads to a dependency on the phase term φ=2πf₀τ−πkτ²−φ_{TX} resulting effectively in a sinusoidal fluctuation around e. It can be shown that the actual error can be approximated by

$${e}_{F T} = \sqrt{2} π k {T}_{s} τ cos ( 2 φ + \frac{π}{4} ) + π k τ {T}_{s} ( N - 1 ) .$$

The phase error e_{FT} depends on the phase term φ=2πf₀τ−πkτ²−φ_{TX} and therefore effectively on the phase φ_{TX} which is to be determined.

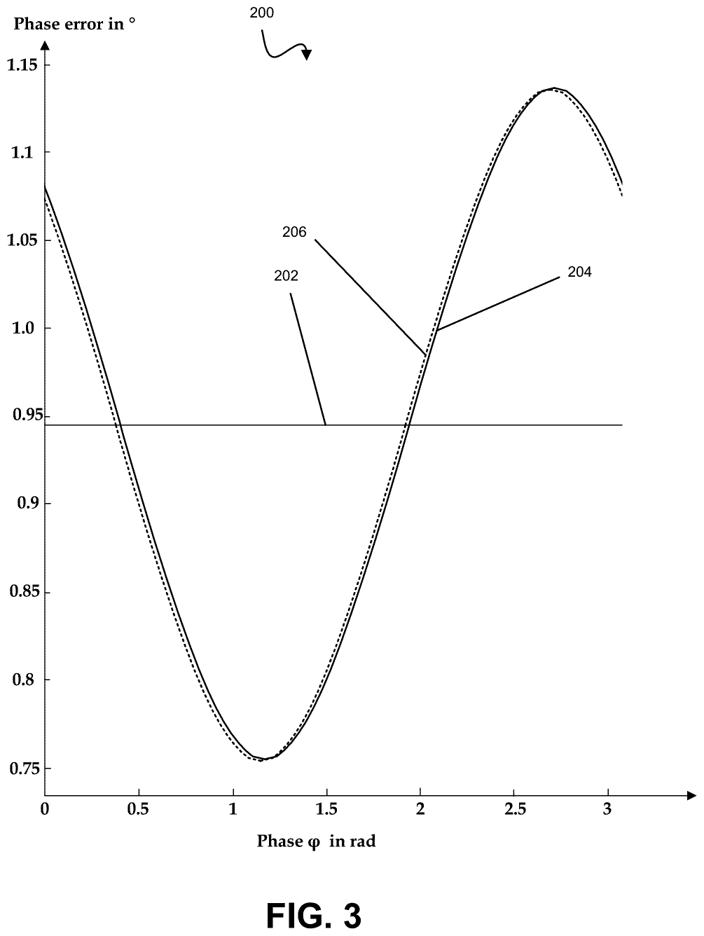

FIG. 3 is a diagram 200 showing the above estimations of the phase errors as a function of the phase term φ. A curve 202 shows the phase error

$$e = \frac{1}{N} \cdot {\sum }_{n = 0}^{N - 1} 2 π k τ n {T}_{s} = π k τ {T}_{s} ( N - 1 )$$

which was calculated to be e=0.945° and is independent of the phase term φ. A curve 202 shows the phase error introduced by the digital Fourier Transformation (DFT) and a curve 204 shows the above described estimation of the phase error introduced by the

$$DFT {e}_{F T} = \sqrt{2} π k {T}_{s} τ cos ( 2 φ + \frac{π}{4} ) + π k τ {T}_{s} ( N - 1 ) .$$

Note that curves 202 and 204 have a mean value of πkτTₛ(N−1).

It can be observed that the curve 204 is almost identical to the curve 202 showing that the introduced phase error can be accurately corrected using the approximation outlined above.

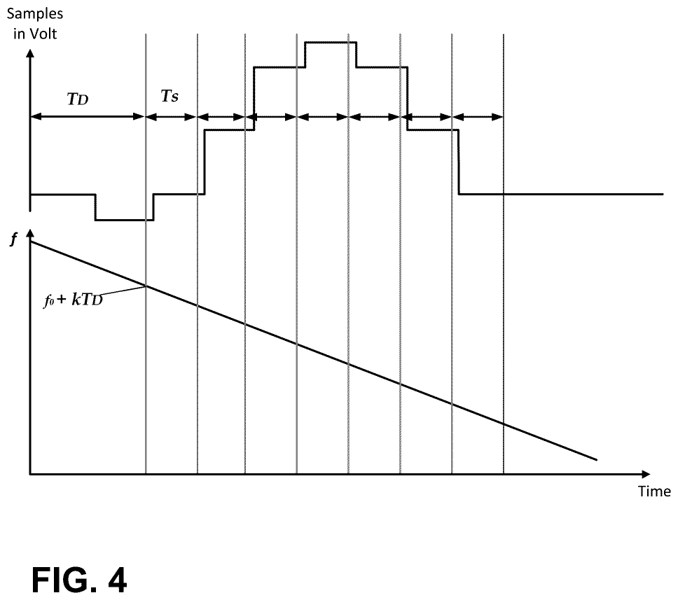

It is also to be noted that a delayed start of the sampling may introduce a further phase error which will be described with respect to FIG. 4.

FIG. 4 shows the sampling of the down-converted signal with a delay time T_{D}. This results in replacing the frequency f₀ by the effective frequency f₀+kT_{D}. Note that FIG. 4 shows a decreasing ramp with a negative slope K. The set of measurement values is obtained by

$$s [ n ] = s ( n {T}_{s} ) = \frac{{A}_{1} \cdot {A}_{2}}{2} \cdot co s ( 2 π n ( k τ {T}_{s} + \frac{1}{N} ) + 2 π k τ {T}_{D} + 2 π {f}_{{0}^{T}} - {φ}_{T X} ) .$$

It can be observed from the above equation that an additional term 2πkτT_{D} is introduced by the delay time TD which also can be calculated and corrected for.

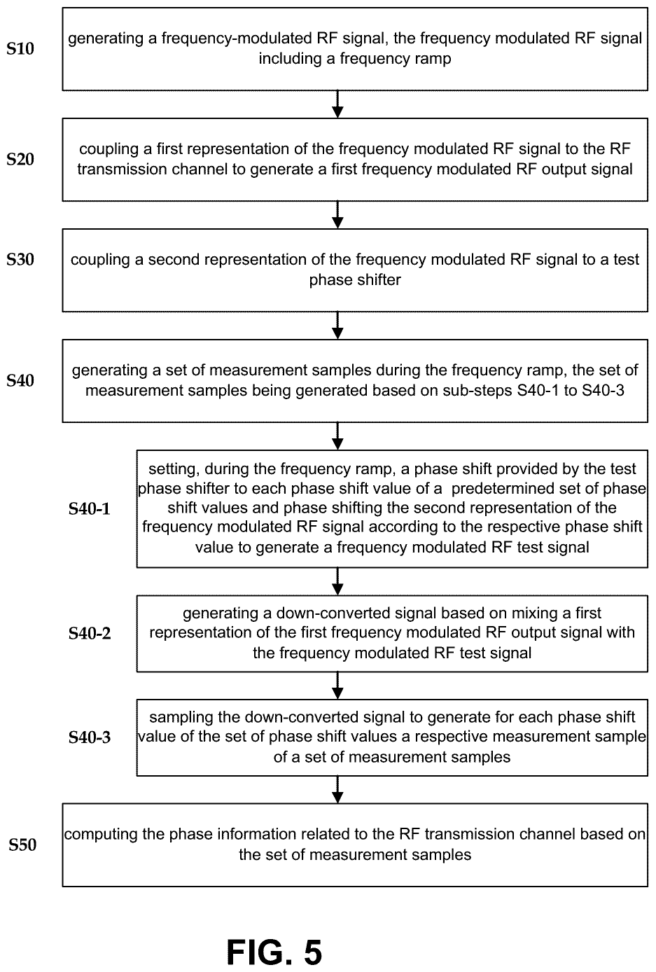

A basic flow diagram example of a method using the proposed concept is now described with respect to FIG. 5. The method starts by generating a frequency-modulated RF signal, the frequency-modulated RF signal including a frequency ramp, S10. A first representation of the frequency-modulated RF signal is coupled to the RF transmission channel to generate a first frequency-modulated RF output signal, S20. A second representation of the frequency-modulated RF signal is coupled to a test phase shifter, S30. A set of measurement samples is generated during the frequency ramp, the set of measurement samples being generated based on sub-steps S40-1 to S40-3. Sub-step S40-1 the setting, during the frequency ramp, of a phase shift provided by the test phase shifter to each phase shift value of a predetermined set of phase shift values and phase shifting the second representation of the frequency-modulated RF signal according to the respective phase shift value to generate a frequency-modulated RF test signal. Sub-step S40-2 includes the generating of a down-converted signal based on mixing a first representation of the first frequency-modulated RF output signal with the frequency-modulated RF test signal. Sub-step S40-3 includes the sampling of the down-converted signal to generate for each phase shift value of the set of phase shift values a respective measurement sample of a set of measurement samples. Finally in Step S50, the phase information related to the RF transmission channel is computed based on the set of measurement samples.

### Aspects

In addition to the above described examples, the following examples are disclosed herein.

Aspect 1 is a method for determining phase information related to an RF transmission cannel, the method comprising: generating a frequency-modulated RF signal, the frequency-modulated RF signal including a frequency ramp, coupling a first representation of the frequency-modulated RF signal to the RF transmission channel to generate a first frequency-modulated RF output signal, coupling a second representation of the frequency-modulated RF signal to a test phase shifter, generating a set of measurement samples during the frequency ramp, the set of measurement samples being generated based on: setting, during the frequency ramp, a phase shift provided by the test phase shifter to each phase shift value of a predetermined set of phase shift values and phase shifting the second representation of the frequency-modulated RF signal according to the respective phase shift value to generate a frequency-modulated RF test signal, generating a down-converted signal based on mixing a first representation of the first frequency-modulated RF output signal with the frequency-modulated RF test signal, sampling the down-converted signal to generate for each phase shift value of the set of phase shift values a respective measurement sample of a set of measurement samples, and computing the phase information related to the RF transmission channel based on the set of measurement samples.

Aspect 2 is the method according to Aspect 1, wherein the sampling of the down-converted signal is time aligned with the setting of a phase shift.

Aspect 3 is the method according to Aspect 2, wherein a time interval between two consecutive settings of the phase shift corresponds to a time interval between two consecutive samplings of measurement samples.

Aspect 4 is the method according to any of Aspects 1 to 3, wherein computing the phase information comprises generating first order harmonic information related to a first order harmonic included in the set of measurements values.

Aspect 5 is the method according to Aspect 4, wherein generating first order harmonic information comprises a Fourier-Transformation of the set of measurement values and wherein the first order harmonic information corresponds to a first order harmonic Fourier-Transformation coefficient.

Aspect 6 is the method according to Aspect 4 or 5, wherein the first order harmonic information includes an imaginary part and a real part and determining the phase information is based on using the imaginary part and the real part.

Aspect 7 is the method according to Aspect 6, wherein the method further comprises: estimating a phase error correction value and determining the phase information based on the phase error correction value.

Aspect 8 is the method according to Aspect 7, wherein the phase error correction value is estimated depending on a slope of the frequency ramp.

Aspect 9 is the method according to any of Aspects 7 or 8, wherein the phase error correction value is estimated depending on a sampling rate used in the sampling of the down-converted signal.

Aspect 10 is the method according to any of Aspect 7 to 9, wherein the phase error correction value is estimated depending on a RF delay time corresponding to a difference in arrival time between the first frequency-modulated RF output signal and the frequency-modulated RF test signal.

Aspect 11 is the method according to any of Aspects 7 to 10, wherein the phase error correction value is estimated depending on the number of phase shift values in the set of phase shift values.

Aspect 12 is the method according to any of Aspects 7 to 11, wherein the phase error correction value is estimated depending on a time difference between a start of the frequency ramp and a start of a sampling of the down-converted signal.

Aspect 13 is the method according to any of Aspects 1 to 12, wherein a point in time at which the phase shift is changed from a previous applied phase shift value to a currently applied phase shift value is offset from a point in time at which the down-converted signal is sampled to generate the respective measurement sample corresponding to the currently applied phase shift value.

Aspect 14 is the method according to any of Aspects 1 to 13 further comprising storing the phase information related to the transmission channel in memory and setting a phase shift of a phase shifter in the transmission channel based on the stored phase information.

Aspect 15 is the method according to any of Aspect 1 to 14, further comprising determining whether the phase information exceeds a predetermined criterion, and, in case the phase information exceeds a predetermined criterion, generating a monitoring alert information.

Aspect 16 is the method according to any of Aspects 1 to 15, further comprising coupling a second representation of the first frequency-modulated RF output signal to an antenna for transmitting, receiving a reflection signal of the second representation of the first frequency-modulated RF signal from an object and processing the reflection signal to determine at least one of a distance or a velocity of the object or a direction-of-arrival.

Aspect 17 is the method according to any of Aspects 1 to 16, wherein the down-converted signal is low-pass filtered prior to the sampling.

Aspect 18 is a radar MMIC device comprising: a local oscillator to generate a frequency-modulated RF signal including a frequency ramp, an RF transmission channel, a test phase shifter, a first coupler configured to couple a first representation of the frequency-modulated RF signal to the RF transmission channel and a second representation of the frequency-modulated RF signal to the test phase shifter, wherein the RF transmission channel is configured to generate a first frequency-modulated RF output signal based on the frequency-modulated RF signal, and wherein the test phase shifter is configured to phase-shift the second representation of the frequency-modulated RF signal according to a phase shift applied to the test phase shifter and to generate a frequency-modulated RF test signal, a second coupler coupled to the RF transmission channel to generate a first representation of the frequency-modulated RF output signal, a mixer coupled to the test phase shifter and the second coupler to receive the first representation of the frequency-modulated RF output signal and the frequency-modulated RF test signal, wherein the mixer is further configured to generate a down-converted signal based on mixing the first representation of the frequency-modulated RF output signal with the frequency-modulated RF test signal, a controller to set the phase shift applied to the test phase shifter during the frequency ramp to each phase shift value of a predetermined set of phase shift values, a sampler to sample the down-converted signal to generate for each phase shift value of the set of phase shift values a respective measurement sample of a set of measurement samples, and a processor to compute phase information related to the transmission channel based on the set of measurement samples.

Aspect 19 is the radar MMIC device according to Aspect 18, wherein the controller is configured to align in time the setting of a phase shift with the sampling of the down-converted signal.

Aspect 20 is the radar MMIC device method according to Aspect 18 or 19, wherein the processor is configured to compute the phase information based on generating first order harmonic information related to a first order harmonic included in the set of measurements values.

Aspect 21 is the radar MMIC device according to Aspect 20, wherein the first harmonic information includes an imaginary part and a real part and wherein the processor is configured to compute the phase information based on the imaginary part and the real part.

Aspect 22 is the radar MMIC device according to any of Aspects 18 to 21, wherein the processor is configured to estimate a phase error correction value and to compute the phase information based on the phase error correction value.

Aspect 23 is the radar MMIC device according to any of Aspects 18 to 22 wherein the controller is further configured to determine whether the computed phase information exceeds a predetermined criterion, and, in case the phase information exceeds a predetermined criterion, to generate a monitoring alert information.

Although specific examples have been illustrated and described herein, it will be appreciated by those of ordinary skill in the art that a variety of alternate and/or equivalent implementations may be substituted for the specific examples shown and described without departing from the scope of the present implementation. This application is intended to cover any adaptations or variations of the specific examples discussed herein. Therefore, it is intended that this implementation be limited only by the claims and the equivalents thereof.

It should be noted that the methods and devices including its preferred implementations as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the implementation and are included within its spirit and scope. Furthermore, all examples and implementations outlined in the present document are principally intended expressly to be only for explanatory purposes to help the reader in understanding the principles of the proposed methods and systems. Furthermore, all statements herein providing principles, aspects, and implementations of the implementation, as well as specific examples thereof, are intended to encompass equivalents thereof.

1. A method for determining phase information related to a radio frequency (RF) transmission channel, the method comprising:
generating a frequency-modulated RF signal, the frequency-modulated RF signal including a frequency ramp;
coupling a first representation of the frequency-modulated RF signal to the RF transmission channel to generate a first frequency modulated frequency-modulated RF output signal;
coupling a second representation of the frequency-modulated RF signal to a test phase shifter; and
generating a set of measurement samples during the frequency ramp, the set of measurement samples being generated based on:
setting, during the frequency ramp, a phase shift provided by the test phase shifter to each phase shift value of a predetermined set of phase shift values;
phase shifting the second representation of the frequency-modulated RF signal according to each phase shift value of the predetermined set of phase shift values to generate a frequency-modulated RF test signal;
generating a down-converted signal based on mixing a first representation of the first frequency-modulated RF output signal with the frequency-modulated RF test signal;
sampling the down-converted signal to generate, for each phase shift value of the predetermined set of phase shift values, a respective measurement sample of a set of measurement samples; and
computing the phase information related to the RF transmission channel based on the set of measurement samples.

2. The method according to claim 1, wherein sampling of the down-converted signal is time aligned with setting the phase shift provided by the test phase shifter.

3. The method according to claim 2, wherein a time interval between two consecutive settings of the phase shift corresponds to a time interval between two consecutive samplings of measurement samples of the set of measurement samples.

4. The method according to claim 1, wherein computing the phase information comprises generating first order harmonic information related to a first order harmonic included in the set of measurement samples.

5. The method according to claim 4, wherein generating the first order harmonic information comprises a Fourier-Transformation of the set of measurement values, and
wherein the first order harmonic information corresponds to a first order harmonic Fourier-Transformation coefficient.

6. The method according to claim 4, wherein the first order harmonic information includes an imaginary part and a real part, and
wherein determining the phase information is based on using the imaginary part and the real part.

7. The method according to claim 6, wherein the method further comprises:
estimating a phase error correction value; and
determining the phase information based on the phase error correction value.

8. The method according to claim 7, wherein the phase error correction value is estimated based on a slope of the frequency ramp.

9. The method according to claim 7, wherein the phase error correction value is estimated based on a sampling rate used for sampling the down-converted signal.

10. The method according to claim 7, wherein the phase error correction value is estimated based on a RF delay time corresponding to a difference in time between the first frequency-modulated RF output signal and the frequency-modulated RF test signal.

11. The method according to claim 7, wherein the phase error correction value is estimated based on a number of phase shift values in the predetermined set of phase shift values.

12. The method according to claim 7, wherein the phase error correction value is estimated based on a time difference between a start of the frequency ramp and a start of sampling the down-converted signal.

13. The method according to claim 1, wherein a point in time at which the phase shift is changed from a previous applied phase shift value to a currently applied phase shift value is offset from a point in time at which the down-converted signal is sampled to generate the respective measurement sample corresponding to the currently applied phase shift value.

14. The method according to claim 1, further comprising:
storing the phase information related to the RE transmission channel in memory, and
setting a phase shift of a phase shifter in the RE transmission channel based on the stored phase information.

15. The method according to claim 1, further comprising:
determining whether the phase information exceeds a predetermined criterion, and,
in case the phase information exceeds the predetermined criterion, generating monitoring alert information.

16. The method according to claim 1, further comprising:
coupling a second representation of the first frequency-modulated RF output signal to an antenna for transmitting the second representation of the first frequency-modulated RF signal;
receiving a reflection signal of the second representation of the first frequency-modulated RF signal from an object; and
processing the reflection signal to determine at least one of a distance or a velocity of the object or a direction-of-arrival.

17. The method according to claim 1, further comprising:
low-pass filtering the down-converted signal prior to sampling the down-converted signal.

18. A radar monolithic microwave integrated circuit (MMIC) device, comprising:
a local oscillator configured to generate a frequency-modulated RF signal including a frequency ramp;
an RF transmission channel;
a test phase shifter;
a first coupler configured to couple a first representation of the frequency-modulated RF signal to the RF transmission channel and couple a second representation of the frequency-modulated RF signal to the test phase shifter,
wherein the RF transmission channel is configured to generate a first frequency-modulated RF output signal based on the first representation of the frequency-modulated RF signal, and
wherein the test phase shifter is configured to generate a frequency-modulated RF test signal by phase-shifting the second representation of the frequency-modulated RF signal according to a predetermined set of phase shift values such that a phase shift applied by the test phase shifter for each phase shift value of the predetermined set of phase shift values to generate the frequency-modulated RF test signal;
a second coupler coupled to the RF transmission channel to generate a first representation of the frequency-modulated RF output signal;
a mixer coupled to the test phase shifter and the second coupler to receive the first representation of the frequency-modulated RF output signal and the frequency-modulated RF test signal,
wherein the mixer is further configured to generate a down-converted signal based on mixing the first representation of the frequency-modulated RF output signal with the frequency-modulated RF test signal;
a controller configured to set the phase shift applied by the test phase shifter during the frequency ramp to each phase shift value of the predetermined set of phase shift values;
a sampler configured to sample the down-converted signal to generate, for each phase shift value of the predetermined set of phase shift values, a respective measurement sample of a set of measurement samples; and
a processor configured to compute phase information related to the RE transmission channel based on the set of measurement samples.

19. The radar MMIC device according to claim 18, wherein the controller is configured to align in time the setting of the phase shift with sampling the down-converted signal.

20. The radar MMIC device method according to claim 18, wherein the processor is configured to compute the phase information based on generating first order harmonic information related to a first order harmonic included in the set of measurement samples.

21. The radar MMIC device according to claim 20, wherein the first harmonic information includes an imaginary part and a real part, and
wherein the processor is configured to compute the phase information based on the imaginary part and the real part.

22. The radar MMIC device according to claim 18, wherein the processor is configured to estimate a phase error correction value and compute the phase information based on the phase error correction value.

23. The radar MMIC device according to claim 18, wherein the controller is further configured to determine whether the phase information exceeds a predetermined criterion, and, in case the phase information exceeds the predetermined criterion, generate a monitoring alert information.
